(19) United States
(12) Patent Application Publication
(10) Pub. No.: US 2004/0041497 A1
(43) Pub. Date: Mar. 4, 2004

(54) Piezoelectric sounding body and piezoelectric electroacoustic transducer using the same

(76) Inventors: Kazuaki Hamada, Toyama-ken (JP); Tetsuo Takeshima, Toyama-shi (JP); Manabu Sumita, Toyama-shi (JP); Keiichi Kami, Toyama-shi (JP); Mitsunori Ishimasa, Toyama-shi (JP)

Correspondence Address: KEATING & BENNETT LLP, Suite 312, 10400 Eaton Place, Fairfax, VA, 22030, US

(21) Appl. No.: 10/459,545

(22) Filed: Jun. 12, 2003

(30) Foreign Application Priority Data
Jun. 12, 2002 (JP) 2002-170759

(51) Int. Cl. H01L 41/09

(52) U.S. Cl. 310/330

(57) ABSTRACT

A piezoelectric sounding body includes a metal plate, an insulating layer disposed on the top surface of the metal plate, and a piezoelectric body in which a plurality of piezoelectric ceramic layers are laminated with an internal electrode disposed therebetween and the piezoelectric ceramic layers are polarized in the thickness direction so as to be opposite to each other, the top and bottom surfaces of which external electrodes are provided, and on the bottom surface of which is bonded to the insulating layer. The external electrodes and the internal electrode are connected to each other through the end surface of the piezoelectric body, a lead-out electrode electrically separated from the top external electrode is disposed on the top surface of the piezoelectric body, the lead-out electrode is connected to the internal electrode through the end surface of the piezoelectric body, and bending vibration is generated by applying an alternating signal between the top external electrode and the lead-out electrode.

### BACKGROUND OF THE INVENTION

1. Field of the Invention

The present invention relates to a piezoelectric sounding body such as a piezoelectric sounder, a piezoelectric speaker, etc., and a piezoelectric electroacoustic transducer in which a piezoelectric sounding body is included.

2. Description of the Related Art Recently, in electronic equipment, home appliances, portable telephones, and other such apparatuses, a piezoelectric sounder and a piezoelectric speaker providing an alarm and an operational cue have been widely used. In such piezoelectric acoustic components, a piezoelectric sounding body, in which a unimorph-type diaphragm is constructed by attaching a metal plate to one surface of a piezoelectric body made of a piezoelectric ceramic on the top and bottom surfaces of which electrodes are disposed, is used and the piezoelectric sounding body is housed in a case.

In such a piezoelectric sounding body, the bottom electrode of the piezoelectric body is attached to the metal plate with adhesive and the bottom electrode is made conductive with the metal plate. Therefore, when an alternating signal (AC signal or square-wave signal) is applied between the top electrode of the piezoelectric body and the metal plate, the alternating signal is applied between the top and bottom electrodes of the piezoelectric body and accordingly, the piezoelectric body expands and contracts in the plane direction. However, since the metal plate does not expand and contract, bending vibration is performed in the piezoelectric sounding body to generate a sound wave.

Then, when the piezoelectric sounding body is housed in the case and electrically connected to the outside, it is common to solder one lead wire to the top electrode of the piezoelectric body and to solder the other lead wire to the metal plate. However, since the lead wires are soldered manually, the workability is poor and a bad connection is likely to occur because the piezoelectric sounding body is reduced in size.

A construction, in which a pair of terminals are provided in the case in advance and the piezoelectric sounding body is connected to the terminals by using conductive adhesive, has been proposed (Japanese Unexamined Patent Application Publication No. 2000-310990). In this case, since a conductive adhesive can be coated on the top surface of the piezoelectric sounding body using a coating device such as a dispenser, etc., the coating process can be automated and a defective connection becomes unlikely to occur.

However, in order to glue the bottom electrode of the piezoelectric body to the metal plate and make it electrically conductive therebetween, both have to have ohmic contact therebetween. Ohmic contact can be defined as an electrically conductive state which is realized by minute pits and projections of the electrode or minute pits and projections of the metal plate through a thin-film insulating adhesive, and, in order to obtain the electrical reliability, it is required to control the thickness of adhesive and the adhesive strength. When a conductive adhesive is used instead of an insulating adhesive, it is not required to make the connection an ohmic contact, but, since the conductive adhesive contains a lot of filler, a sufficient adhesive strength cannot be obtained between the piezoelectric body and the metal plate.

Furthermore, a piezoelectric sounding body including a piezoelectric body of a laminated construction is also known. That is, in Japanese Unexamined Patent Application Publication No. 61-103397, a piezoelectric buzzer having a construction, in which a piezoelectric body is obtained such that a plurality of ceramic green sheets are laminated with an internal electrode therebetween and simultaneously fired is attached to a metal plate, is disclosed. When the piezoelectric body has a twolayer construction, the external electrodes on the top and bottom surfaces are connected to each other through an electrode provided on an end surface of the piezoelectric body and the internal electrode is led to the outside through another electrode provided on an end surface of the piezoelectric body. Furthermore, when the piezoelectric body has a three-layer construction, an external electrode and an internal electrode are connected to each other through an end surface of the piezoelectric body at each layer. In the case of a piezoelectric body having such a laminated construction, it is required to provide electrodes on the end surface of the piezoelectric body and the end surface electrode and the metal plate are disposed close to each other. Accordingly, when both have different potentials, they may be short-circuited.

### SUMMARY OF THE INVENTION

In order to overcome the problems described above, preferred embodiments of the present invention provide a piezoelectric sounding body in which a piezoelectric body is not electrically connected to the outside through a metal plate and the metal plate is attached to the piezoelectric body and solely used as a supporting plate for bending vibration and to provide a piezoelectric electroacoustic transducer including the piezoelectric sounding body.

According to a first preferred embodiment of the present invention, a piezoelectric sounding body includes a metal plate, an insulating layer disposed on the top surface of the metal plate, and a piezoelectric body made of a piezoelectric ceramic which is polarized in the thickness direction, on the top and bottom surfaces of which external electrodes are provided, and the bottom surface of which is bonded on the insulating layer. In the piezoelectric sounding body, a lead-out electrode is electrically separated from the top external electrode and is made conductive to the bottom external electrode through an end surface of the piezoelectric body, and, when an alternating signal is applied between the top external electrode and the lead-out electrode, bending vibration is generated.

Furthermore, according to a second preferred embodiment of the present invention, a piezoelectric sounding body includes a metal plate, an insulating layer disposed on the top surface of the metal plate, and a piezoelectric body in which a plurality of piezoelectric ceramic layers are laminated with an internal electrode therebetween and the piezoelectric ceramic layers are alternatively polarized in the thickness direction, on the top and bottom surfaces of which external electrodes are provided, and the bottom surface of which is bonded on the insulating layer. In the piezoelectric sounding body, the internal electrodes are alternatively connected to the external electrodes at both end surfaces of the piezoelectric body. On the top surface of the piezoelectric body, a lead-out electrode electrically is separated from the top external electrode, and the lead-out electrode is connected to an external electrode and an internal electrode, which are not connected to the top external electrode, through the end surface of the piezoelectric body. When an alternating signal is applied between the top external electrode and the lead-out electrode, bending vibration is generated.

According to a third preferred embodiment of the present invention, in a piezoelectric electroacoustic transducer, a piezoelectric sounding body according to the above-described preferred embodiments of the present invention is housed inside an enclosure having first and second terminals provided therein, the periphery portion of the piezoelectric sounding body is fixed to the inner portion of the enclosure and sealed, and the top external electrode of the piezoelectric sounding body is connected to the first terminal by conductive adhesive and the lead-out electrode is connected to the second terminal by conductive adhesive.

According to the first preferred embodiment of the present invention, a piezoelectric body having a single plate construction is preferably used in a piezoelectric sounding body. This piezoelectric body is bonded to the top surface of a metal plate through an insulating layer. Therefore, the bottom external electrode of the piezoelectric body is electrically insulated from the metal plate. On the top surface of the piezoelectric body, a lead-out electrode, which is electrically separated from the top external electrode and is made conductive to the bottom external electrode through the end surface of the piezoelectric body, is provided. Accordingly, an alternating signal is applied between the top external electrode and the lead-out electrode which causes the piezoelectric body to expand and contract in the plane direction in order to generate a bending vibration. In the piezoelectric sounding body, the metal plate is attached to the piezoelectric body and functions only as a supporting plate for bending vibration, and the metal plate does not input and output any electrical signal. That is, ohmic contact between the bottom external electrode and the metal plate is not required, and, since electrical conduction to the outside is made through the two electrodes provided on the top, the electric reliability can be assured.

According to a second preferred embodiment of the present invention, a piezoelectric body having a laminated construction is used in a piezoelectric sounding body. When the piezoelectric body of a laminated construction is used, the electric field strength can be made double or higher compared with the case where a piezoelectric body of a single plate construction is used, even if both have the same thickness, and accordingly higher sound pressure can be obtained. The external electrode and the internal electrode of the piezoelectric body are connected to each other through the end surface of the piezoelectric body at each layer, but, when the end surface electrode and the metal plate are disposed close to each other and they have different potentials, both are short-circuited to each other. However, since an insulating layer is disposed on the surface of the metal plate, a short-circuit between the end surface electrode and the metal plate can be surely prevented. Also in this case, bending vibration is performed and a sound wave can be generated such that the two electrodes are provided on the surface of the piezoelectric body and an alternating signal is applied between the electrodes. The metal plate functions only as a supporting plate for generation of the bending vibration and does contribute to inputting and outputting any electrical signal.

According to a preferred embodiment of the present invention, it is desirable that the metal plate is larger than the piezoelectric body, and the insulating layer is continuously formed on the surface of the extension portion so as to extend outside the piezoelectric body. The metal plate and the piezoelectric body may have the same dimension, but, when the periphery portion of the metal plate is supported, the displacement of the piezoelectric body becomes easier by making the metal plate larger than the piezoelectric body and a larger sound pressure can be obtained. When such a piezoelectric sounding body is attached to the outside by using conductive adhesive, although the conductive adhesive is also coated on the surface of the metal plate, an insulating layer is disposed in the coating area and accordingly, the conductive adhesive is not made conductive to the metal plate.

According to a preferred embodiment of the present invention, it is desirable that the insulating layer includes an insulating resin material as the coating. When a resin having excellent insulating characteristics such as polyimide resin, epoxy resin, or other suitable material, is used as a coating, even a thin film of a few μm in thickness can provide assured insulating characteristics. Moreover, since the coating has a fixed rigidity and does not absorb the difference of the displacement between the piezoelectric body and the metal plate, good bending deformation can be obtained.

According to a preferred embodiment of the present invention, the insulating layer may be formed by oxidation treatment of the surface of the metal plate. In this case, any problems such as peel off of the insulating layer do not occur and the insulating characteristics can be stably maintained for a long time.

According to the third preferred embodiment of the present invention, when the piezoelectric sounding body is housed and fixed inside an enclosure having first and second terminals provided and the connection between the top external electrode and the first terminal and between the lead-out electrode and the second terminal of the piezoelectric sounding body is performed, a piezoelectric electroacoustic transducer can be efficiently manufactured. In particular, the manual processing such as soldering lead wires can be eliminated and the electrical connection can be made by coating conductive adhesive from above the piezoelectric sounding body. Thus, the operation can be automated and, as a result, a piezoelectric electroacoustic transducer having stabilized quality can be obtained.

Other features, elements, characteristics and advantages of the present invention will become more apparent from the following detailed description of preferred embodiments thereof with reference to the attached drawings.

### BRIEF DESCRIPTION OF THE DRAWINGS

FIG. 1 an exploded perspective view of a first preferred embodiment of a piezoelectric electroacoustic transducer according to the present invention;

FIG. 2 is a top view of the piezoelectric electroacoustic transducer in FIG. 1, but with the cover and adhesive removed;

FIG. 3 is a sectional view taken on line A-A of FIG. 2;

FIG. 4 is a partially enlarged view of FIG. 3;

FIG. 5 is an exploded perspective view of a piezoelectric sounding body;

FIG. 6 is a sectional view of the piezoelectric sounding body in FIG. 5;

FIG. 7 shows an insert-molded case with terminals;

FIG. 8A shows sound pressure characteristics of a piezoelectric sounding body having a piezoelectric body of a single plate construction;

FIG. 8B shows sound pressure characteristics of a piezoelectric sounding body having a piezoelectric body having a laminated construction;

FIG. 9 is a sectional view of a second preferred embodiment of a piezoelectric sounding body according to the present invention; and

FIG. 10 is a sectional view of a third preferred embodiment of a piezoelectric sounding body according to the present invention.

### DETAILED DESCRIPTION OF PREFERRED EMBODIMENTS

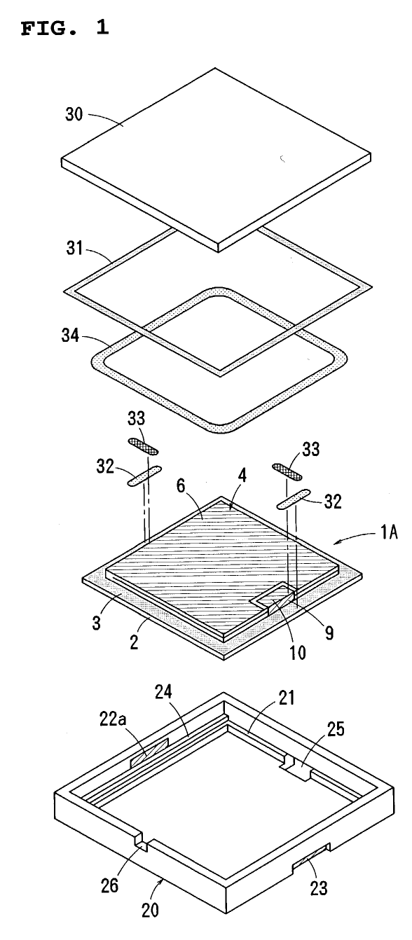

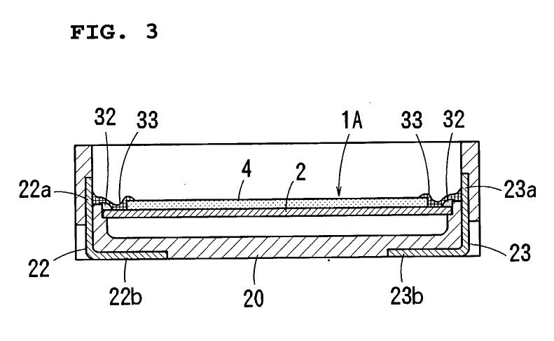

FIGS. 1 to 4 show a piezoelectric sounder as a first preferred embodiment of a piezoelectric electroacoustic transducer according to the present invention. This piezoelectric sounder preferably includes a unimorph-type piezoelectric sounding body 1A, a case 20, and a cover 30.

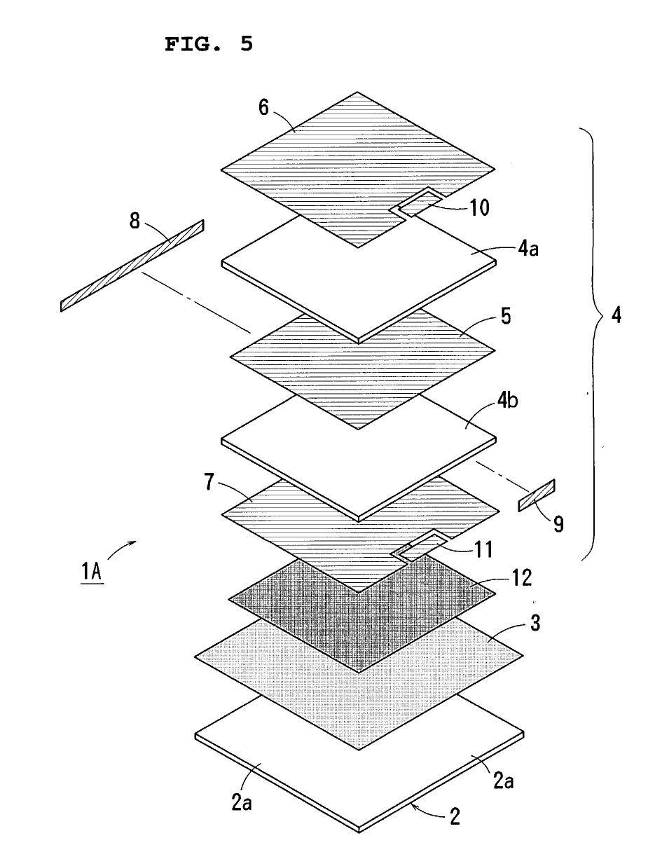

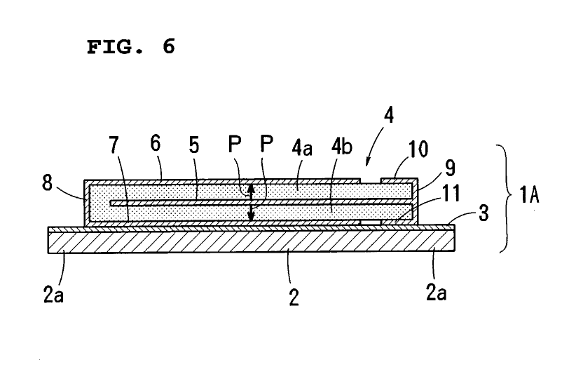

As shown in FIGS. 5 and 6, the piezoelectric sounding body 1A preferably includes a substantially square metal plate 2, an insulating layer 3 disposed on the entire surface of the metal plate 2, and a substantially square piezoelectric body 4 fixed on the insulating layer 3 by using adhesive, which is smaller than the metal plate 2. An elastic material is desirable for the metal plate 2 and, for example, phosphor bronze, 42Ni, or other suitable material, is preferably used. Moreover, when 42 Ni is used for the metal plate 3, since the thermal expansion coefficient is close to that of ceramics (PZT, etc.), the reliability is further increased. The insulating layer 3 can be constructed by using a resin coating such as polyimide resin, epoxy resin, or other suitable material, or by forming an oxide film on the surface of the metal plate by oxidation treatment.

The piezoelectric body 4 is constructed such that two piezoelectric ceramic layers 4a and 4b in the state of a green sheet are laminated with an internal electrode 5 therebetween and fired, and external electrodes 6 and 7 are provided on almost the entire area of the top and bottom surfaces of the piezoelectric ceramic layers 4a and 4b. The piezoelectric ceramic layers 4a and 4b are polarized in the thickness direction so as to be opposite to each other as shown by arrow marks P in FIG. 6. One end of the metal plate 5 is exposed at one end surface of the piezoelectric body 4 and the other end is a fixed distance away from the end surface of the piezoelectric body 4. The top and bottom external electrodes 6 and 7 of the piezoelectric body 4 are connected to each other through one end surface electrode 8, and the internal electrode 5 is connected to lead-out electrodes 10 and 11 formed on the top and bottom surfaces of the piezoelectric body 4 through another end surface electrode 9. The lead-out electrodes 10 and 11 are small electrodes disposed along the middle of one side of the piezoelectric body 4 and electrically separated from the external electrodes 6 and 7 on the top and bottom surfaces. One end surface electrode 8 is as long as one side of the piezoelectric body 4, but the other end surface electrode 9 has a length corresponding to the length of the lead-out electrodes 10 and 11. Moreover, in this preferred embodiment, although the lead-out electrodes 10 and 11 are disposed not only on the top surface, but also on the bottom surface to eliminate directional properties, the lead-out electrode 11 on the bottom surface may be omitted. Furthermore, the lead-out electrodes 10 and 11 may be made as long as one side of the piezoelectric body 4. The bottom surface of the piezoelectric body 4 is bonded on the middle upper surface of the insulating layer 3 by using an adhesive 12 such as epoxy adhesive, etc. (see FIG. 5). The metal plate 2 is larger than the piezoelectric body 4 and the insulating layer 3 is disposed on the surface of the extension portion 2a so as to be extended outside the piezoelectric body 4.

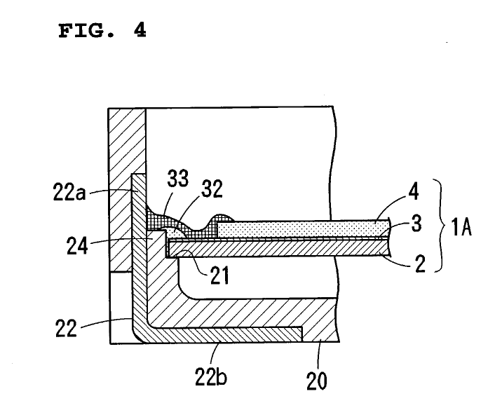

The case 20 preferably constitutes a substantially squareshaped box having a bottom wall and four side walls made of an insulating material such as ceramics, resin, or other material. When the case 20 is formed by using a resin material, a heat-resistant material such as LPC (liquid crystal polymer), SPS (syndiotactic polystyrene), PPS (polyphenylene sulfide), epoxy, or other suitable material, is desirable to use. A supporting portion 21 for supporting the entire periphery portion of the sounding body 1A is disposed inside the side walls of the case 20, and terminals 22 and 23 to be electrically connected to the top external electrode 6 and the lead-out electrode 10 of the sounding body 1A are exposed on the inside surfaces of the opposing two side walls. Furthermore, a spacing wall portion 24 is integrally disposed in the case 20 so as to be positioned between the supporting portion 21 and the exposed portion of the terminals 22 and 23 (see FIG. 4). When the metal plate 2 is mounted on the supporting portion 21 as to be described later, this spacing wall portion 24 functions as a spacer preventing the metal plate 2 from being in contact with the terminals 22 and 23.

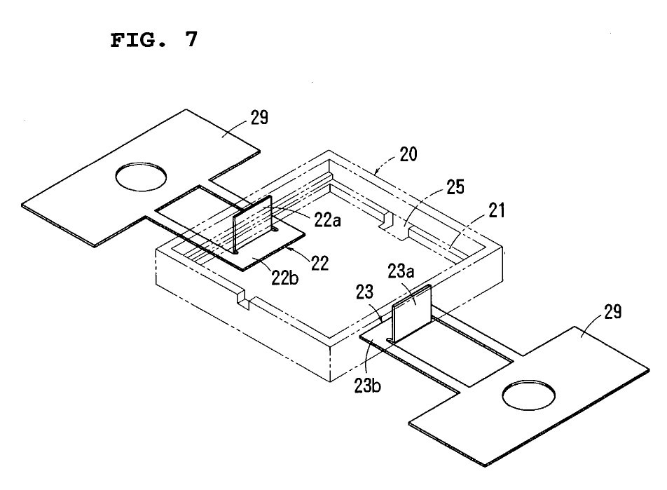

The terminals 22 and 23 are insert molded in the case 20, and, as shown in FIG. 7, the outside portions 22a and 23a of the terminals 22 and 23, which are integrally punched out from a hoop material 29, are substantially perpendicularly bent and these bent portions are made internal connection portions to the sounding body 1A. Thus, the outer dimensions of the case 20 can be reduced such that the internal connection portions 22a and 23a are arranged upright relative to the bottom surface of the case (sounding body 1A) and accordingly, the internal connection portions 22a and 23a do not extend inside the case 20. The inside portions 22b and 23b of the terminals 22 and 23 are bent so as to be along the bottom surface of the case 20 and these portions become external connection portions.

A lower sound release hole 25 is formed in the bottom portion of one of the side walls where the terminals 22 and 23 of the case 20 are not provided and a groove 26 for sound release is provided in the top portion of the other side wall. A cover 30 in the present preferred embodiment is preferably formed by using the same material as the case 20 so as to be flat. The groove 26 becomes an upper sound release hole when the cover 30 is bonded to the top portion of the side walls of the case 20 by using an adhesive 31. Moreover, the cover 30 is not be required to be flat, but may be made cap-shaped, that is, substantially concave in section. Furthermore, the upper sound release hole 26 is not required to be made of the groove provided in the top portion of the side wall of the case 20, and may be formed as a hole provided in the cover 30.

The piezoelectric sounding body 1A is housed in the case 20 such that the metal plate 2 faces the bottom wall and the periphery portion is mounted on the supporting portion 21. Next, an insulation material 32 is coated so as to define a line between the periphery portion of the metal plate 2 and the internal connection portions 22a and 23a of the terminals 22 and 23 and hardened. Any insulating adhesive may be used as the insulating material 32, but it is desirable to use an elastic adhesive such as urethane and silicone adhesives. Next, a conductive adhesive 33 is coated between the outside external electrode 6 and the terminal 22 and between the lead-out electrode 10 and the terminal 23 so as to be substantially perpendicular to the insulating material 32 and hardened. It is desirable to use an elastic urethane adhesive including conductive fillers therebetween as the conductive adhesive 33. Although the conductive adhesive 33 is coated on the metal plate 2, since the insulating layer 3 is provided on the metal plate in advance and the periphery portion of the metal plate 2 is covered by the insulating material 32, the conductive adhesive 33 is not in direct contact with the metal plate 2. Next, the whole periphery portion of the metal plate 2 is fixed to the case 20 by using an adhesive 34. Any commonly known insulating adhesive may be used as the adhesive 34, but it is desirable to use an elastic adhesive such as urethane and silicone adhesives. As described above, after the sounding body 1A has been fixed to the case 20, a cover 30 is bonded to the upper opening portion of the case by using the adhesive 31. When the cover 30 is bonded, an acoustic space is defined between the cover 30 and the sounding body 1A and between the sounding body 1A and the case 20 to establish a surface mounting type piezoelectric sounder.

As described above, since an elastic material is used as the adhesives 32, 33, and 34 for fixing the sounding body 1A to the case 20, the displacement of the sounding body 1A can be maximized and accordingly it becomes possible to obtain a high sound pressure. Furthermore, since the electrodes (the outside external electrode 6 and the lead-out electrode 10) of the sounding body 1A are directly connected to the electrodes (the terminals 22 and 23) of the case 20 by using the conductive adhesive 33, the electrical reliability increases compared with the case in which electrical conduction takes place through the metal plate 2. In addition, since the conductive adhesive 33 can be coated from above the case 20 by using a coating device such as a dispenser, the coating operation can be easily automated and the manufacturing efficiency and the quality can be improved compared with the case where the lead wires are soldered.

When a signal having substantially the same frequency as the resonance frequency of the sounding body 1A is applied between the terminals 22 and 23 provided in the case 20, the piezoelectric body 4 expands and contracts in the plane direction and, since the metal plate 2 does not expand and contract, bending deformation of the sounding body 1A as a whole occurs. Since the periphery portion of the sounding body 1A is supported by the case 20 and the space on the top and bottom of the sounding body 1A is sealed by the adhesive 34, a fixed sound wave can be generated. This sound wave is released to the outside through the upper sound release hole 26.

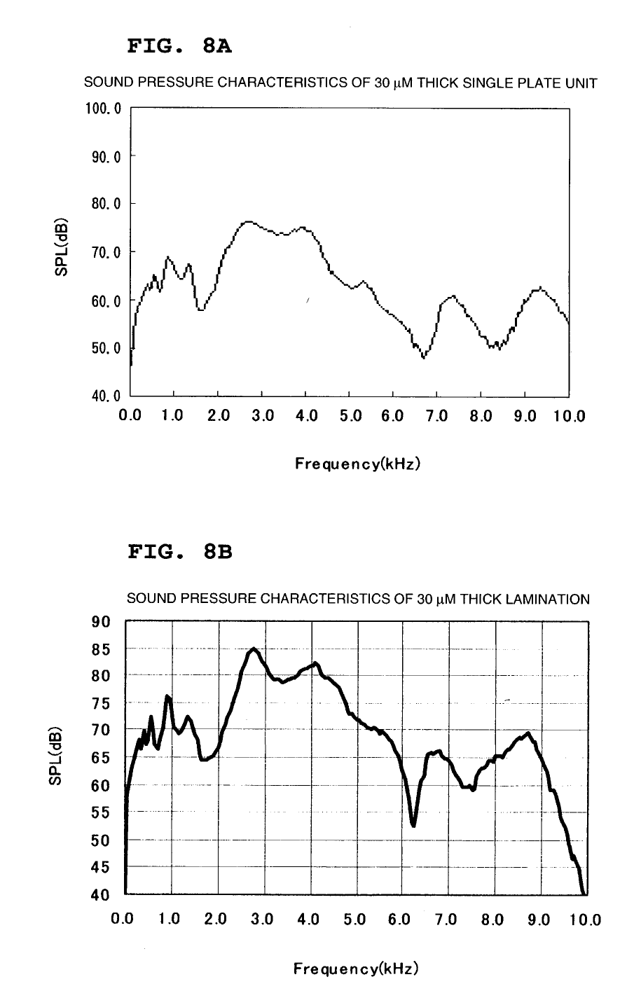

FIG. 8A shows sound pressure characteristics of a piezoelectric sounding body having a piezoelectric body with a single plate construction, and FIG. 8B shows sound pressure characteristics of the piezoelectric sounding body 1A having the piezoelectric body 4 with a laminated construction. Both have the same construction except for the piezoelectric bodies. Moreover, the dimensions of the piezoelectric body 4 are, for example, approximately 6.8 mm×6.8 mm×30 μm (in the case of two layers, each layer is about 15 μm thick), a 42 Ni plate of approximately 8.0 mm×8.0 mm×20 μm is preferably used as the metal plate, and an approximately 3 μm-thick polyimide coat is used as the insulating layer 3. As is clearly understood in FIG. 8, when the piezoelectric body 4 of a laminated construction is used, the sound pressure is improved by about 10 dB in the range of about 2.5 kHz to about 4 kHz.

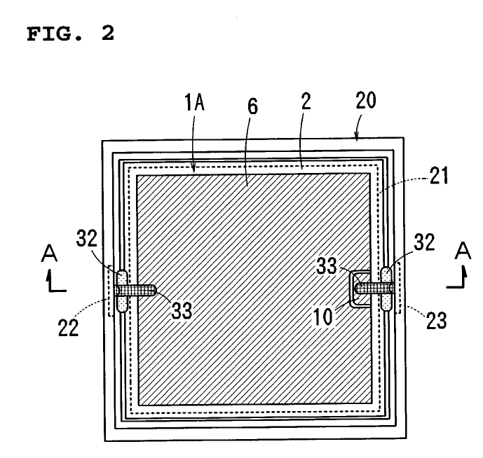

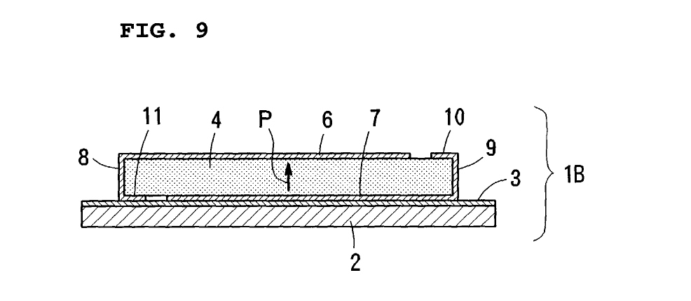

FIG. 9 shows a second preferred embodiment of a piezoelectric sounding body according to the present invention. In this preferred embodiment, the piezoelectric body 4 is of a single plate construction is described. The piezoelectric body 4 is polarized in the thickness direction as shown by an arrow mark P, and the external electrodes 6 and 7 are provided on the top and bottom surfaces. The lead-out electrode 10 electrically separated from the top external electrode 6 is disposed on the top surface of the piezoelectric body 4, and the lead-out electrode 11 electrically separated from the bottom external electrode is disposed on the bottom surface of the piezoelectric body 4. The top external electrode 6 is conductive to the leadout electrode 11 through the end surface electrode 8 of the piezoelectric body 4, and the bottom external electrode 7 is conductive to the lead-out electrode 10 through the end surface electrode 9 of the piezoelectric body 4. Moreover, the lead-out electrode 11 on the bottom is arranged to eliminate directional characteristics of the piezoelectric body 4, and accordingly, the lead-out electrode 11 is not necessarily required. The bottom surface of the piezoelectric body 4 is bonded to the insulating layer 3 disposed on the surface of the metal plate 2 to constitute a piezoelectric sounding body 1B. This sounding body 1B is fixed to the supporting portion of the case in the same way as in the first preferred embodiment (see FIGS. 2 to 4), and the top external electrode 6 and the lead-out electrode 10 are connected to the terminals of the case by using a conductive adhesive, respectively.

In the case of a unimorph-type sounding body including a related piezoelectric body of a single plate construction, the bottom electrode was required to be made in ohmic contact with the metal plate. However, according to preferred embodiments of the present invention, since the insulating layer 3 is disposed on the surface of the metal plate 2, the bottom electrode 7 is not conductive to the metal plate 2 and also not required to be conductive to the metal plate 2. Therefore, complicated control of the thickness of adhesive becomes unnecessary and accordingly the manufacturing process becomes easier. Conduction to the outside is performed through the external electrode 6 and the lead-out electrode 10 provided on the surface of the piezoelectric body 4. Although the electrodes 8 and 9 provided on the end surfaces of the piezoelectric body 4 become close to the metal plate 2, the insulating layer 3 can surely prevent the end surface electrodes 8 and 9 from contacting the metal plate.

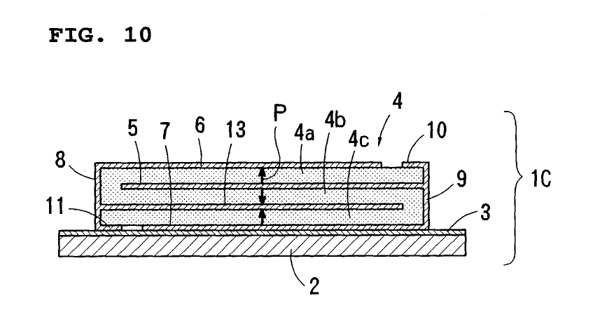

FIG. 10 shows a third preferred embodiment of a piezoelectric sounding body according to the present invention. In the present preferred embodiment, the piezoelectric body 4 preferably has a three-layer laminated construction. In the piezoelectric body 4, three piezoelectric ceramic layers 4a to 4c in the state of a green sheet are laminated with internal electrodes 5 and 13 therebetween and fired, and external electrodes 6 and 7 are provided in almost the entire area of the top and bottom surfaces of the piezoelectric body 4. The piezoelectric ceramic layers 4a to 4c are polarized in the thickness direction so as to be opposite to each other as shown by arrow marks in FIG. 10. One end of the internal electrode 5 is exposed at one end surface of the piezoelectric body 4 and one end of the internal electrode 13 is exposed at the opposite end surface of the piezoelectric body 4. Furthermore, the leadout electrode 10 electrically separated from the top external electrode 6 is disposed at one end of the surface of the piezoelectric body 4, and the lead-out electrode 11 separated from the bottom side external electrode 7 is disposed at the other end of the bottom surface. Then, the top external electrode 6, the internal electrode 13, and the bottom lead-out electrode 11 are connected to each other through the end surface electrode 8, and the bottom external electrode 7, the internal electrode 5, and the top lead-out electrode 10 are connected to each other through the end surface electrode 9. Also in this case, the bottom lead-out electrode 11 is not necessarily required.

The bottom surface of the piezoelectric body 4 is bonded on the insulating layer 3 disposed on the surface of the metal plate 2 by adhesive to constitute a piezoelectric sounding body 1C. This sounding body 1C is fixed to the supporting portion of the case in the same way as in the first preferred embodiment (see FIGS. 2 to 4) and the top external electrode 6 and the lead-out electrode 10 are connected to the terminals of the case by a conductive adhesive, respectively. In this case, since the piezoelectric body 4 has a laminated construction, if it has the same thickness as that of the piezoelectric body 4 of a single plate construction (see FIG. 9), the thickness of each layer becomes about one third and accordingly, the electric field strength increases to about three fold. Therefore, even if the same signal is applied, the sound pressure can be increased.

The present invention is not limited to the above-described preferred embodiments. For example, the metal plate and the piezoelectric body are not limited to a substantially square shape, but also may have a substantially rectangular or substantially round shape. A piezoelectric body having a laminated construction is not limited to two-layer and threelayer constructions, but also may have a four or more layered construction. The insulating layer disposed on the surface of the metal plate is not necessarily required to cover the whole surface of the metal plate, but it is required to cover the portion where the piezoelectric body is bonded. Preferably, when the terminals of the enclosure are connected to the piezoelectric body by using a conductive adhesive, it is desirable to provide an insulating layer in the area where the conductive adhesive is coated. In the above-described preferred embodiments, although the enclosure includes a concave case and a cover for closing the opening portion of the case, the construction is not limited to that. Furthermore, the terminals are not limited to insert-molded terminals, but also the terminals may be made of electrode films formed by plating, sputtering, or other suitable process.

As is clearly understood in the above description, according to a first preferred embodiment of the present invention, in a piezoelectric sounding body including a piezoelectric body having a single plate construction, the piezoelectric body is bonded on the surface of a metal plate through an insulating layer and a lead-out electrode electrically separated from a top external electrode and being conductive to a bottom external electrode through the side surface of the piezoelectric body is provided, and accordingly, two electrodes can be led from the surface of the piezoelectric body to the outside. Because of that, it is not required to arrange the bottom electrode to be in ohmic contact with the metal plate different from the case of related products and the electric reliability can be assured. Furthermore, the metal plate joined to the piezoelectric body is only required to function as a supporting plate which performs bending vibration, and, since no electrical signal is input and output, electrical conduction is not required to be controlled between the piezoelectric body and the metal plate, the manufacture process becomes easier, and a piezoelectric sounding body having stable characteristics can be obtained. Furthermore, although the end surface electrode and the metal plate are disposed close to each other, since an insulating layer is disposed on the surface of the metal plate, the end surface electrode is not shortcircuited to the metal plate.

Furthermore, according to a second preferred embodiment of the present invention, since a piezoelectric body having a laminated construction is preferably used, the sound pressure can be improved compared with a piezoelectric sounding body using a piezoelectric body having a single plate construction. Furthermore, in the same way as in the first preferred embodiment of the present invention, even if the end surface electrode is disposed close to the metal plate, since an insulating layer is disposed on the surface of the metal plate, a short circuit between the end surface electrode and the metal plate can be surely prevented, and, since the metal plate does not take contribute to input and output of any electrical signal, the manufacture of a piezoelectric sounding body is made easy and a piezoelectric sounding body having stable characteristics can be obtained.

According to a third preferred embodiment of the present invention, a piezoelectric sounding body of the present invention is housed in an enclosure, the periphery portion of the sounding body is fixed to the enclosure by using adhesive, and, in the piezoelectric sounding body, a top external electrode is connected to a first terminal portion and a leadout electrode is connected to a second terminal portion by conductive adhesive. Therefore, manual work such as soldering lead wires can be eliminated, the assembly can be easily done by coating adhesive or conductive adhesive from above the piezoelectric sounding body, the operation can be automated, and, as a result, a piezoelectric electroacoustic transducer having stabilized quality can be obtained.

While preferred embodiments of the invention have been described above, it is to be understood that variations and modifications will be apparent to those skilled in the art without departing the scope and spirit of the invention. The scope of the invention, therefore, is to be determined solely by the following claims.

What is claimed is:

1. A piezoelectric sounding body comprising:
a metal plate;
an insulating layer disposed on a top surface of the metal plate;
a piezoelectric body made of a piezoelectric ceramic which is polarized in the thickness direction thereof, external electrodes provided on top and bottom surfaces of the piezoelectric body, and the bottom surface of the piezoelectric body is bonded on the insulating layer; and
a lead-out electrode which is electrically separated from the top external electrode and which is conductive with the bottom external electrode through an end surface of the piezoelectric body; wherein
when an alternating signal is applied between the top external electrode and the lead-out electrode, bending vibration is generated.

2. A piezoelectric sounding body as claimed in claim 1, wherein the metal plate is larger than the piezoelectric body.

3. A piezoelectric sounding body as claimed in claim 1, wherein the insulating layer continuously extends on the surface of an extension portion extended outside the piezoelectric body.

4. A piezoelectric sounding body as claimed in claim 1, wherein the insulating layer is defined by a coated insulating resin material.

5. A piezoelectric sounding body as claimed in claim 1, wherein the insulating layer is defined by an oxidized surface of the metal plate.

6. A piezoelectric electroacoustic transducer, wherein a piezoelectric sounding body as claimed in claim 1 is housed inside an enclosure having first and second terminals provided therein, a periphery portion of the piezoelectric sounding body is fixed to the inner portion of the enclosure and sealed therein, and the top external electrode of the piezoelectric sounding body is connected to the first terminal by conductive adhesive and the lead-out electrode is connected to the second terminal by conductive adhesive.

7. A piezoelectric sounding body as claimed in claim 1, wherein the piezoelectric sounding body is a unimorph-type piezoelectric sounding body.

8. A piezoelectric sounding body as claimed in claim 1, wherein the metal plate is substantially square.

9. A piezoelectric sounding body as claimed in claim 1, wherein the piezoelectric body is substantially square.

10. A piezoelectric sounding body as claimed in claim 1, wherein the external electrode on the bottom surface of the piezoelectric body is not conductive to the metal plate.

11. A piezoelectric sounding body as claimed in claim 1, wherein the insulating layer is arranged to prevent the external electrodes of the piezoelectric body from contacting the metal plate.

12. A piezoelectric sounding body as claimed in claim 1, wherein the piezoelectric sounding body has one of a single plate construction and a multiple-layer laminated construction.

13. A piezoelectric sounding body comprising:
a metal plate;
an insulating layer disposed on a top surface of the metal plate; and
a piezoelectric body in which a plurality of piezoelectric ceramic layers are laminated with an internal electrode therebetween and the piezoelectric ceramic layers are polarized in the thickness direction so as to be opposite to each other, external electrodes disposed on the top and bottom surfaces of the piezoelectric body, and the bottom surface of the piezoelectric body is bonded on the insulating layer; wherein
in the piezoelectric body, the external electrode and the internal electrode are connected to each other through an end surface of the piezoelectric body at each layer;
on the top surface of the piezoelectric body, a leadout electrode is arranged so as to be electrically separated from the top external electrode;
the lead-out electrode is connected to an external electrode and an internal electrode, which are not connected to the top external electrode, through the end surface of the piezoelectric body; and
when an alternating signal is applied between the top external electrode and the lead-out electrode, bending vibration is generated.

14. A piezoelectric sounding body as claimed in claim 13, wherein the metal plate is larger than the piezoelectric body, and the insulating layer continuously extends on the surface of the extension portion extended outside the piezoelectric body.

15. A piezoelectric sounding body as claimed in claim 13, wherein the insulating layer is defined by a coated insulating resin material.

16. A piezoelectric sounding body as claimed in claim 13, wherein the insulating layer is defined by an oxidized surface of the metal plate.

17. A piezoelectric electroacoustic transducer, wherein a piezoelectric sounding body as claimed in claim 13 is housed inside an enclosure having first and second terminals provided therein, a periphery portion of the piezoelectric sounding body is fixed to the inner portion of the enclosure and sealed therein, and the top external electrode of the piezoelectric sounding body is connected to the first terminal by conductive adhesive and the lead-out electrode is connected to the second terminal by conductive adhesive.

18. A piezoelectric sounding body as claimed in claim 13, wherein the piezoelectric sounding body is a unimorph-type piezoelectric sounding body.

19. A piezoelectric sounding body as claimed in claim 13, wherein the metal plate is substantially square.

20. A piezoelectric sounding body as claimed in claim 13, wherein the piezoelectric body is substantially square.

21. A piezoelectric sounding body as claimed in claim 13, wherein the external electrode on the bottom surface of the piezoelectric body is not conductive to the metal plate.

22. A piezoelectric sounding body as claimed in claim 13, wherein the insulating layer is arranged to prevent the external electrodes of the piezoelectric body from contacting the metal plate.

23. A piezoelectric sounding body as claimed in claim 13, wherein the piezoelectric sounding body has one of a single plate construction and a multiple-layer laminated construction.
